(19) United States
(12) Patent Application Publication
(10) Pub. No.: US 2004/0173803 A1
(43) Pub. Date: Sep. 9, 2004

(54) Interconnect structure having improved stress migration reliability

(75) Inventor: Hyeon-Seag Kim, San Jose, CA (US)

Correspondence Address: FARJAMI & FARJAMI LLP, 26522 LA ALAMEDA AVENUE, SUITE 360, MISSION VIEJO, CA, 92691, US

(73) Assignee: Advanced Micro Devices, Inc.

(21) Appl. No.: 10/382,560

(22) Filed: Mar. 5, 2003

(51) Int. Cl. H01L 27/15

(52) U.S. Cl. 257/81

(57) ABSTRACT

An interconnect structure which has improved stress migration reliability is disclosed. According to one exemplary embodiment, the interconnect structure comprises a top interconnect metal layer, at least one via and a bottom interconnect metal layer. The bottom interconnect metal layer comprises at least one finger. The at least one via electrically connects the top interconnect metal layer to the at least one finger. The finger width of the at least one finger is less than a bottom layer width of the bottom interconnect metal layer. In another embodiment, a method for fabricating the above interconnect structure is disclosed.

### TECHNICAL FIELD

The present invention relates generally to the field of semiconductor devices. More particularly, the present invention relates to interconnect structures in semiconductor devices.

### BACKGROUND ART

Modern semiconductor dies include densely packed circuits which use, among other things, interconnect metal layers and vias for electrical connectivity. For example, a top interconnect metal layer can be electrically connected to a bottom interconnect metal layer by a via or a number of vias.

Disadvantageously, stress migration or stress-induced voiding (“SIV”), i.e. migration of voids in metals due to stress, can reduce or eliminate electrical contact between vias and interconnect metal (“ICM”) layers, which can cause device failure. Stress migration can be particularly troublesome in connections between a via and its associated underlying ICM layer when the width of the underlying ICM layer is much greater than the width of the via, i.e. a high ratio of ICM layer width to via width.

Stress migration can cause small voids in an underlying interconnect metal layer to migrate to beneath a via. These small voids can collectively form into a large void beneath the via. Large voids reduce or eliminate electrical contact between the underlying metal layer and the via. Stress migration can be caused by thermal cycling and process variations such as improper annealing, chemical mechanical polish (“CMP”) processes, copper fillings, barrier/seed quality and dielectric interface quality. Thus, stress migration can cause reduced electrical contact between vias and underlying ICM layers, which causes increased resistivity and can lead to device failure. Accordingly, there exists a strong need in the art to overcome deficiencies of known interconnect structures such as those described above, and for an interconnect structure having improved stress migration reliability.

### SUMMARY

The present invention is directed to an interconnect structure having improved stress migration reliability. The invention addresses and resolves the need in the art for an interconnect structure which has improved stress migration reliability and reduced device failure rates.

According to one exemplary embodiment, the interconnect structure comprises a top interconnect metal layer and at least one via and a bottom interconnect metal layer. The bottom interconnect metal layer includes at least one finger. The at least one via electrically connects the top interconnect metal layer to the at least one finger. The finger width of the at least one finger is less than the bottom interconnect metal layer width. The exemplary embodiment can also comprise an interlayer dielectric situated over the bottom interconnect metal layer and beneath the top interconnect metal layer, where the at least one via is formed within the interlayer dielectric. In another embodiment, the invention is a method for fabricating the above interconnect structure. Other features and advantages of the present invention will become more readily apparent to those of ordinary skill in the art after reviewing the following detailed description and accompanying drawings.

### BRIEF DESCRIPTION OF THE DRAWINGS

FIG. 1A shows a top view of a conventional interconnect structure.

FIG. 1B shows a cross-sectional view of the conventional interconnect structure of FIG. 1.

FIG. 2 is a flowchart illustrating the steps taken to implement an embodiment of the invention.

FIG. 3A shows a top view of an interconnect structure in intermediate stages of formation, according to one embodiment of the invention.

FIG. 3B shows a top view of an interconnect structure in intermediate stages of formation, according to one embodiment of the invention.

FIG. 3C shows a top view of an interconnect structure in intermediate stages of formation, according to one embodiment of the invention.

FIG. 3D shows a top view of an interconnect structure according to one embodiment of the invention.

### DETAILED DESCRIPTION OF THE INVENTION

The present invention is directed to an interconnect structure having improved stress migration reliability. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings.

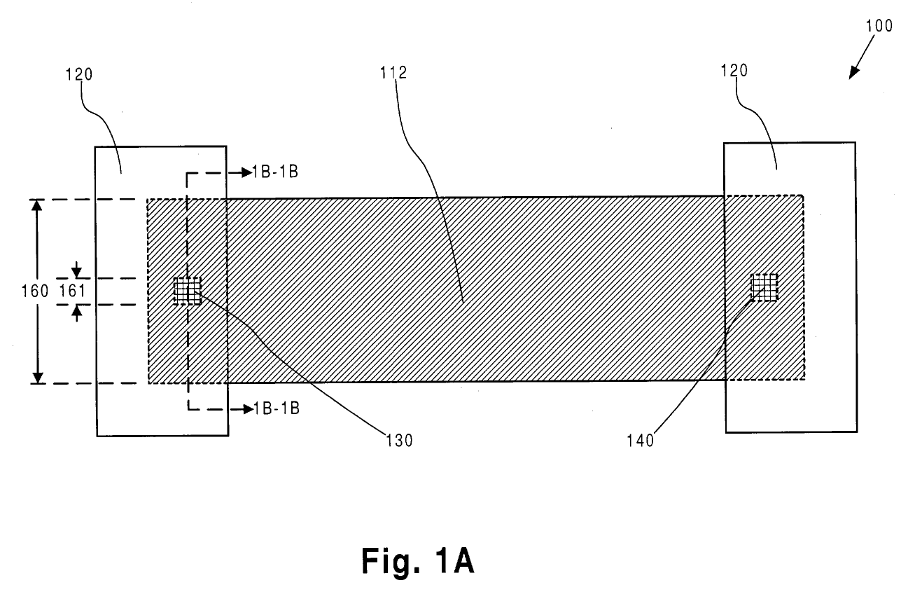

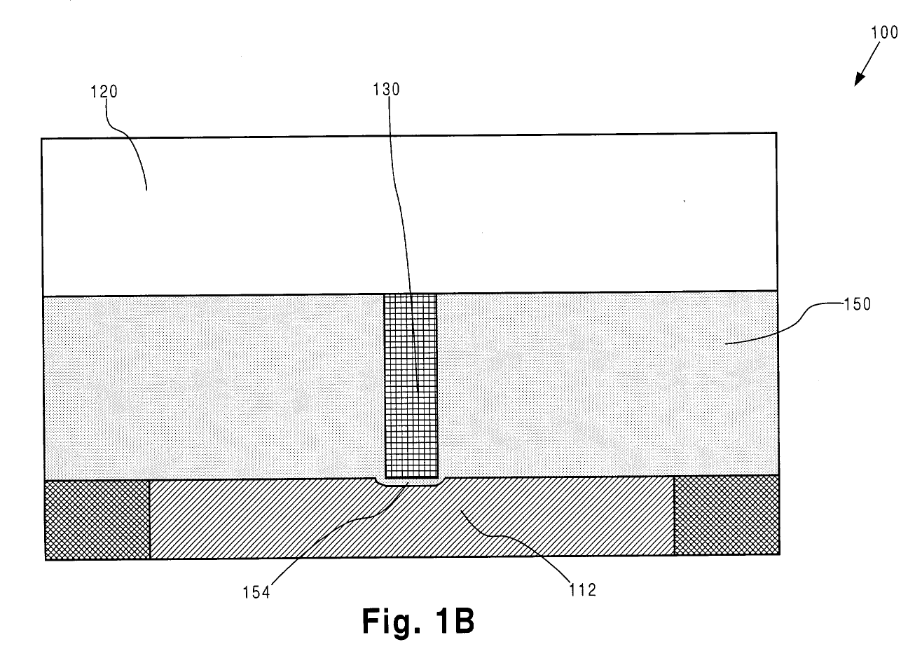

FIG. 1A shows a top view of conventional interconnect structure 100 in a semiconductor die. As shown in FIG. 1A, interconnect structure 100 includes bottom interconnect metal (“ICM”) layer 112, vias 130 and 140 and top ICM layer 120. Bottom ICM layer 112 and top ICM layer 120 can comprise aluminum or copper and can be fabricated by a deposition and patterning process. Vias 130 and 140 can comprise aluminum or copper and are situated within an interlayer dielectric (not shown in FIG. 1A). Bottom ICM layer 112 is electrically connected to top ICM layer 120 by vias 130 and 140. Width 160 of bottom ICM layer 112 is much greater than width 161 of via 130 and thus, as described above, stress migration can cause small voids to form into a large void beneath via 130.

FIG. 1B shows a cross-sectional view along line 1B-1B of conventional interconnect structure 100 in FIG. 1A. As shown in FIG. 1B, interlayer dielectric (“ILD”) 150 and via 130 are situated over bottom ICM layer 112. ILD layer 150 can comprise a low-k dielectric and can be fabricated by a deposition process. Top ICM layer 120 is situated over, and is in contact with, ILD layer 150 and via 130. Void 154 is formed beneath via 130 due to stress migration, which can be caused by thermal cycling and process variations. Void 154 causes reduced electrical contact between via 130 and bottom ICM layer 112, which causes increased resistivity and can lead to device failure.

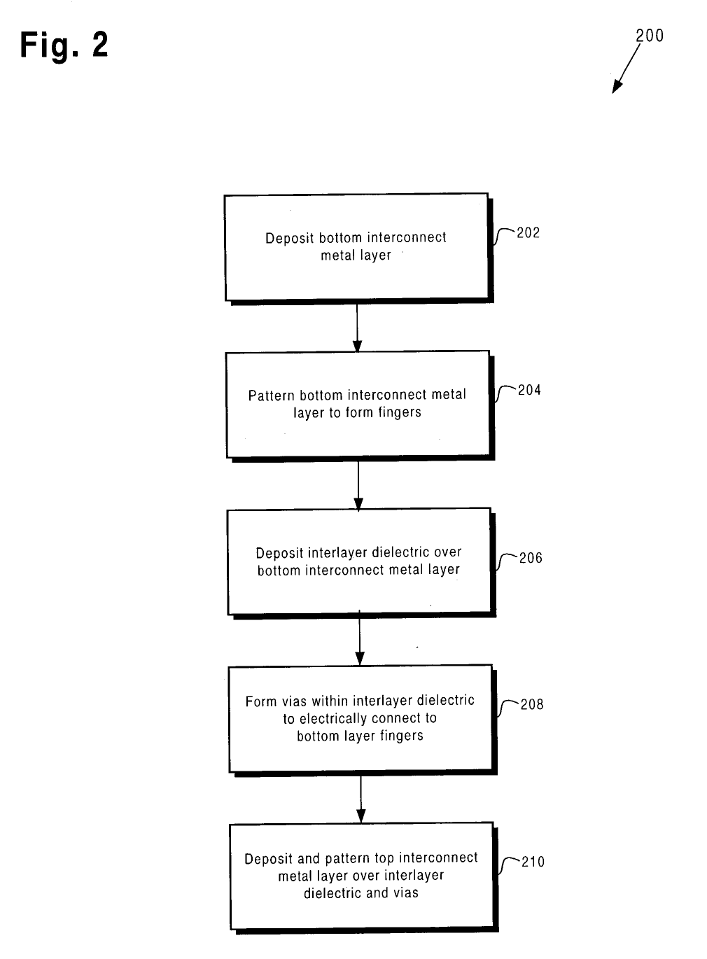

FIG. 2 shows a flowchart illustrating exemplary process steps taken to implement an embodiment of the invention. Certain details and features have been left out of flowchart 200 of FIG. 2 that are apparent to a person of ordinary skill in the art. For example, a step may consist of one or more sub-steps or may involve specialized equipment or materials, as known in the art. While steps 202 through 210 indicated in flowchart 200 are sufficient to describe one embodiment of the present invention, other embodiments of the invention may utilize steps different from those shown in flowchart 200. It is noted that the processing steps shown in flowchart 200 are performed on a wafer which, prior to step 202, includes a substrate.

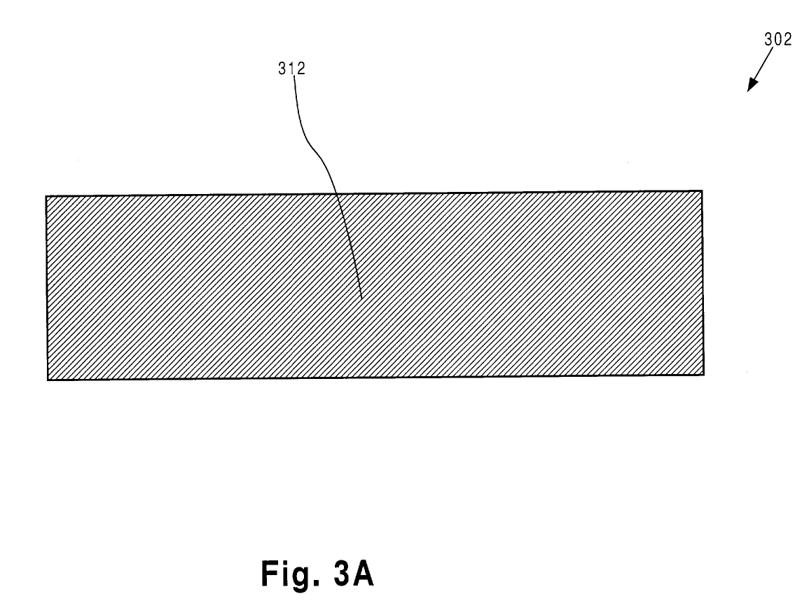

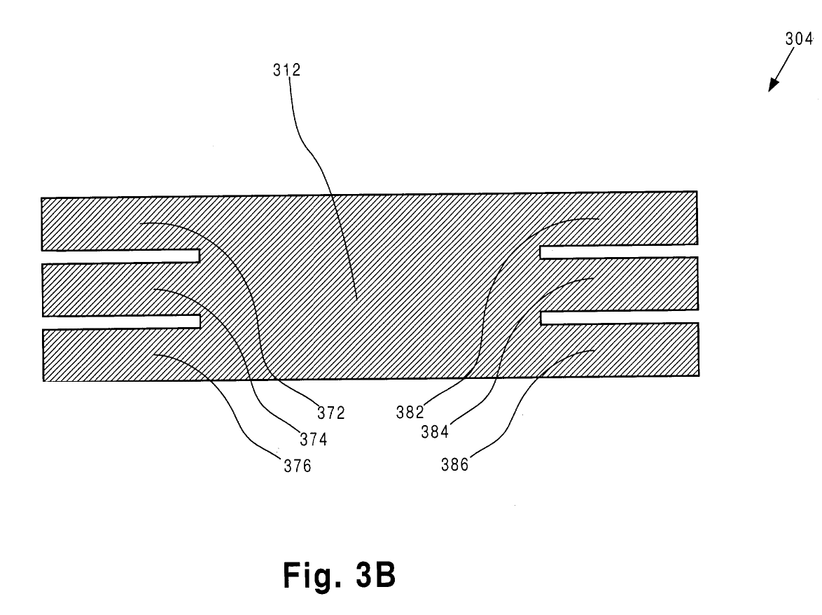

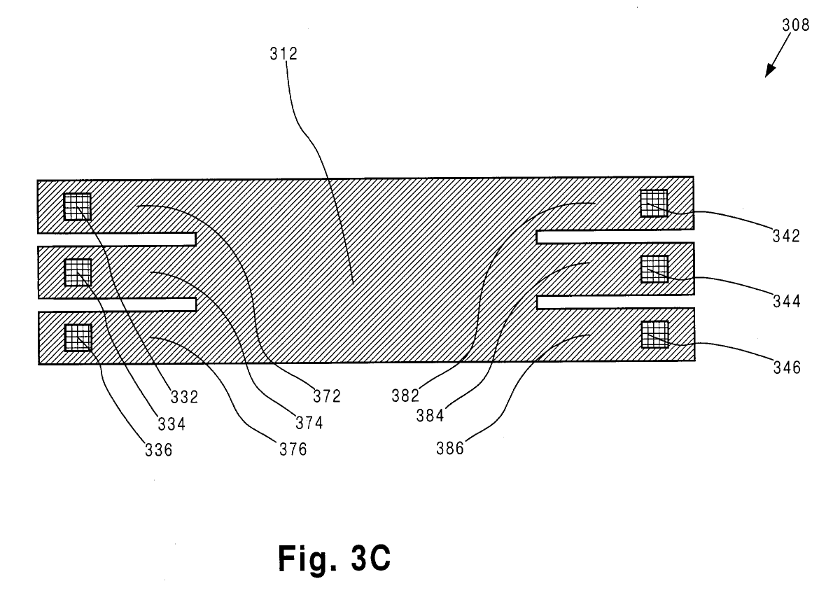

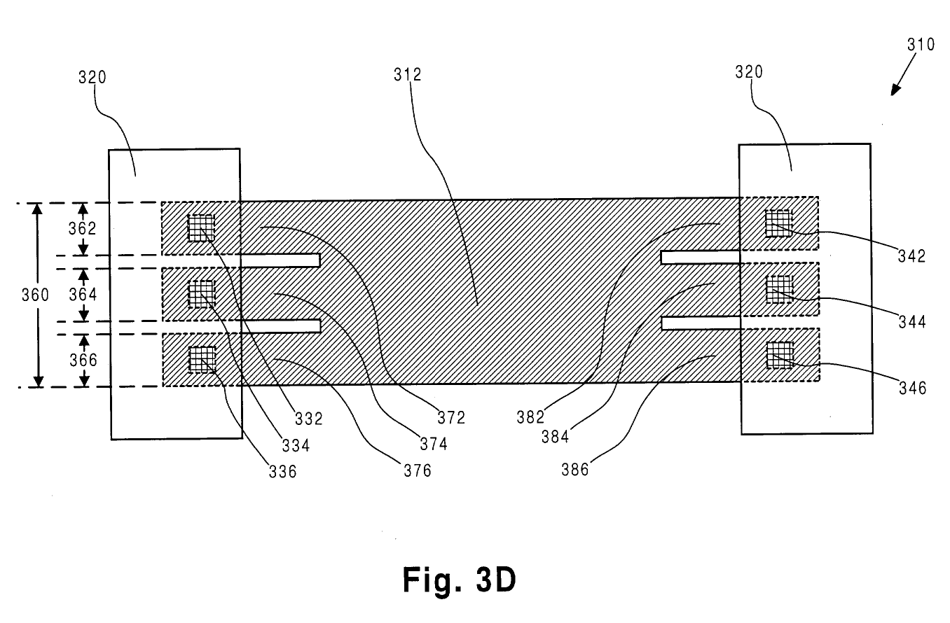

FIGS. 3A, 3B, 3C and 3D show top views of some of the features of an exemplary interconnect structure in intermediate stages of fabrication, formed in accordance with one embodiment of the invention. These intermediate stages of fabrication show some of the features of fabrication of an exemplary interconnect structure, formed in accordance with one exemplary embodiment of the present invention. These fabrication stages are described in greater detail further below in relation to flowchart 200 of FIG. 2.

Referring to FIGS. 2 and 3A, at step 202 of flowchart 200, and as shown in corresponding structure 302 in FIG. 3A, bottom interconnect metal layer 312 is deposited over a substrate (not shown in any of the Figures). Bottom ICM layer 312 can comprise, for example, aluminum or copper. Referring to FIGS. 2 and 3B, at step 204 of flowchart 200, and as shown in corresponding structure 304 in FIG. 3B, bottom ICM layer 312 is patterned to form fingers 372, 374, 376, 382, 384 and 386. The width of fingers 372, 374, 376, 382, 384 and 386 can be approximately equal to each other. In one embodiment, the width of fingers 372, 374, 376, 382, 384 and 386 are equal to a minimum design rule width. Those skilled in the art shall recognize that the finger widths can vary from each other and the number of fingers can vary without departing from the scope of the present invention.

Referring to FIG. 2, at step 206 of flowchart 200, an interlayer dielectric (not shown in FIGS. 3A through 3D) is deposited over bottom ICM layer 312. The interlayer dielectric can comprise a low-k dielectric. Referring to FIGS. 2 and 3C, at step 208 of flowchart 200, and as shown in corresponding structure 308 in FIG. 3C, vias 332, 334, 336, 342, 344 and 346 are formed within the interlayer dielectric (not shown) deposited at step 206. Vias 332, 334, 336, 342, 344 and 346 are situated over, and electrically connected to, fingers 372, 374, 376, 382, 384 and 386, respectively. Vias 332, 334, 336, 342, 344 and 346 can comprise, for example, tungsten or copper.

Referring to FIGS. 2 and 3D, at step 210 of flowchart 200, and as shown in corresponding structure 310 in FIG. 3D, top interconnect metal layer 320 is deposited and patterned over the interlayer dielectric (not shown) and vias 332, 334, 336, 342, 344 and 346. Thus, top ICM layer 320 is situated over, and electrically connected to, vias 332, 334, 336, 342, 344 and 346. Top ICM layer 320 can comprise, for example, aluminum or copper.

FIG. 3D shows interconnect structure 310 formed in accordance with one embodiment of the present invention. As shown in FIG. 3D, structure 310 includes top ICM layer 320, vias 332, 334, 336, 342, 344 and 346 and bottom ICM layer 312, where bottom ICM layer 312 comprises fingers 372, 374, 376, 382, 384 and 386. Bottom ICM layer 312 is electrically connected to top ICM layer 320 by vias 332, 334, 336, 342, 344 and 346. Specifically, fingers 372, 374, 376, 382, 384 and 386 are connected to vias 332, 334, 336, 342, 344 and 346, respectively.

The present invention advantageously increases stress migration reliability by reducing the effective ratio of the width of the bottom ICM layer to via width, while substantially retaining the overall ICM layer width to preserve its low resistance and its high current conduction capability. Referring to FIG. 3D, bottom ICM layer 312 has bottom layer width 360. Fingers 372, 374 and 376 have finger widths 362, 364 and 366, respectively. Finger widths 362, 364 and 366 are each equal to slightly less than approximately one-third of bottom layer width 360. Moreover, a substantial portion of bottom ICM layer 312 has preserved its initial configuration, i.e. a substantial portion of bottom ICM layer 312 is not divided into fingers. However, the effective width of bottom ICM layer 312 in relation to via 332 is approximately equal to finger width 362. Moreover, the effective ratio of the width of bottom ICM layer 312, e.g. finger width 362, to via width, e.g. width of via 332, is significantly reduced, while approximately retaining the overall bottom ICM layer width because the sum of finger widths 362, 364 and 366 is approximately equal to bottom layer width 360. A similar analysis of the remaining fingers, i.e. fingers 382, 384 and 386, and vias, i.e. vias 342, 344 and 346, is not described herein because these elements are substantially similar to the aforementioned fingers and vias.

In comparison to the conventional interconnect structure 100 of FIG. 1A, the embodiment of the present invention of FIG. 3D, reduces the effective ratio of the width of bottom ICM layer 312, e.g. finger width 362, to a via width, e.g. widths of vias 362, 364 and 366, to approximately one-third of the ratio of bottom layer width 160 to via width 161. This reduction in the effective ratio of bottom layer width to via width advantageously increases stress migration reliability, which reduces void migration underneath vias.

In sum, forming interconnect structures in the manner described above advantageously results in an ICM layer comprising fingers, which reduces the effective ratio of bottom layer width to via width. Thus, stress migration within the interconnect structure is reduced. Moreover, in comparison to conventional interconnect structures, electrical contact between vias and underlying ICM layers is more reliable and resistivity is reduced.

From the above description of exemplary embodiments of the invention it is manifest that various techniques can be used for implementing the concepts of the present invention without departing from its scope. Moreover, while the invention has been described with specific reference to certain embodiments, a person of ordinary skill in the art would recognize that changes could be made in form and detail without departing from the spirit and the scope of the invention. For example, the number of fingers or the finger widths referred to in the present application can be modified without departing from the scope of the present invention. The described exemplary embodiments are to be considered in all respects as illustrative and not restrictive. It should also be understood that the invention is not limited to the particular exemplary embodiments described herein, but is capable of many rearrangements, modifications, and substitutions without departing from the scope of the invention.

Thus, an interconnect structure having improved stress migration reliability has been described.

1. An interconnect structure comprising:
a top interconnect metal layer;
at least one via electrically connected to said top interconnect metal layer;
a bottom interconnect metal layer having at least one finger and a bottom layer width, wherein said at least one via is electrically connected to said at least one finger, and wherein said at least one finger has a finger width less than said bottom layer width.

2. The interconnect structure of claim 1, wherein said finger width is equal to a minimum design rule width.

3. The interconnect structure of claim 1, wherein said at least one via is a plurality of vias.

4. The interconnect structure of claim 3, wherein said at least one finger is a plurality of fingers.

5. The interconnect structure of claim 4, wherein each finger of said plurality of fingers is electrically connected to a corresponding via of said plurality of vias.

6. The interconnect structure of claim 1, wherein a plurality of fingers have a plurality of associated finger widths, and wherein a combined finger width of said plurality of associated finger widths is approximately equal to said bottom layer width.

7. The interconnect structure of claim 1, further comprising an interlayer dielectric situated beneath said top interconnect metal layer and over said bottom interconnect metal layer.

8. The interconnect structure of claim 7, wherein said at least one via is situated within said interlayer dielectric.

9. An interconnect structure comprising a top interconnect metal layer and at least one via electrically connected to said top interconnect metal layer, said interconnect structure being characterized by:
a bottom interconnect metal layer having at least one finger and a bottom layer width, wherein said at least one via is electrically connected to said at least one finger, and wherein said at least one finger has a finger width less than said bottom layer width.

10. The interconnect structure of claim 9, wherein said finger width is equal to a minimum design rule width.

11. The interconnect structure of claim 9, wherein said at least one via is a plurality of vias.

12. The interconnect structure of claim 11, wherein said at least one finger is a plurality of fingers.

13. The interconnect structure of claim 12, wherein each finger of said plurality of fingers is electrically connected to a corresponding via of said plurality of vias.

14. A method for fabricating an interconnect structure in a semiconductor die, said method comprising steps of:
depositing a bottom interconnect metal layer over a substrate, wherein said bottom interconnect metal layer has a bottom layer width;
patterning said bottom interconnect metal layer to form at least one finger, wherein said at least one finger has a finger width less than said bottom layer width;
forming at least one via electrically connected to said at least one finger;
depositing and patterning a top interconnect metal layer over said at least one via, wherein said top interconnect metal layer is electrically connected to said at least one via.

15. The method of claim 14, wherein said method further comprises a step of depositing an interlayer dielectric over said bottom interconnect metal layer after said step of patterning said bottom interconnect metal layer and before said step of forming said at least one via.

16. The method of claim 15, wherein said step of forming said at least one via comprises forming said at least one via within said interlayer dielectric to electrically connect said at least one via to said at least one finger.

17. The method of claim 14, wherein said step of patterning said bottom interconnect metal layer to form said at least one finger comprises patterning a plurality of fingers.

18. The method of claim 17, wherein said step of forming at least one via electrically connected to said at least one finger comprises forming a plurality of vias, wherein each finger of said plurality of fingers is electrically connected to a corresponding via of said plurality of vias.

19. The method of claim 14, wherein said finger width is equal to a minimum design rule width.

20. The method of claim 14, wherein said step of patterning said bottom interconnect metal layer to form said at least one finger comprises patterning a plurality of fingers having a plurality of associated finger widths, wherein a combined finger width of said plurality of associated finger widths is approximately equal to said bottom layer width.
